(19) United States
(12) Patent Application Publication
(10) Pub. No.: US 2023/0058070 A1
(43) Pub. Date: Feb. 23, 2023

(54) ACOUSTICALLY-DRIVEN QUANTUM SPIN SENSOR

(71) Applicant: Cornell University, Ithaca, NY (US)

(72) Inventors: Gregory FUCHS, Ithaca, NY (US); Huiyao CHEN, Ithaca, NY (US)

(21) Appl. No.: 17/793,357

(22) PCT Filed: Jan. 22, 2021
(86) PCT No.: PCT/US2021/014733

§ 371 Date: Jul. 15, 2022

Related U.S. Application Data
(60) Provisional application No. 62/965,533, filed on Jan. 24, 2020.

(51) Int. Cl. H03H 9/02; G01R 33/34; G01N 24/10

(52) U.S. Cl. CPC H03H 9/02582; G01R 33/34; G01N 24/10; H03H 9/02015

(57) ABSTRACT

Embodiments described herein provide systems and methods for acoustically driving spin rotations of diamond nitrogen-vacancy (NV) centers using acoustic transducers. The acoustic transducers may comprise devices such as bulk acoustic resonators or surface acoustic resonators. The systems and methods may allow driving of mₛ=0 to mₛ=−1, mₛ=0 to mₛ=+1, mₛ=−1 to mₛ=0, and mₛ=+1 to mₛ=0 single-quantum (SQ) spin transitions without the need to apply magnetic field pulses. This may substantially reduce the size and power requirements of NV center-based sensors. The systems and methods may be used to conduct a variety of measurements, such as measurements of magnetic field, electric field, orientation, strain, or temperature.

### CROSS-REFERENCE

The present application claims priority to U.S. Provisional Patent Application No. 62/965,533, entitled “ACOUSTICALLY-DRIVEN QUANTUM SPIN SENSOR,” filed Jan. 24, 2020, which application is entirely incorporated herein by reference for all purposes.

### STATEMENT REGARDING FEDERALLY SPONSORED RESEARCH

The embodiments described herein were made with government support under grant no. D18AC00024 awarded by the Defense Advanced Research Projects Agency, and grant no. N000141712290 awarded by the Office of Naval Research. The government may have certain rights in the embodiments.

### BACKGROUND

A large interest has developed in determination of spin states in the nitrogen-vacancy (NV) systems. Conventional nitrogen-vacancy (NV) diamond sensors use a light source (typically a laser) to optically pump NV centers into an mₛ=0 initial spin state and then apply either continuous-wave (CW) or pulsed magnetic fields having a frequency that matches a spin transition frequency of the NV center.

A variety of different magnetic pulse protocols can be used. The spin state is allowed to evolve in accordance with a sensing protocol and is then read out via a fluorescence signal emitted by the NV center. However, these sensors are typically high powered and difficult to implement. Consequently, there is a need for alternative systems for driving spin transitions in the NV center.

### SUMMARY

In an aspect, the present disclosure provides a system comprising: a diamond substrate comprising at least one nitrogen-vacancy (NV) center therein; an acoustic transducer mechanically coupled to the diamond substrate; and a controller coupled to the acoustic transducer and configured to cause the acoustic transducer to generate acoustic waves within the diamond substrate to thereby drive a single-quantum (SQ) transition from a first spin state of the NV center to a second spin state of the NV center. In various embodiments, the first spin state comprises an mₛ=0 state and the second spin state comprises an mₛ=−1 state or an mₛ=+1 state. In various embodiments, the first spin state comprises an mₛ=−1 state or an mₛ=+1 state and the second spin state comprises an mₛ=0 state. In various embodiments, the acoustic transducer is selected from the group consisting of: a bulk acoustic resonator (BAR), a high-overtone BAR (HBAR), and a semi-confocal HBAR (SCHBAR). In various embodiments, the acoustic transducer is adhered to the diamond substrate. In various embodiments, the acoustic transducer comprises a first thin metallic film adhered to the diamond substrate, a piezoelectric film adhered to the first thin metallic film, and a second thin metallic film adhered to the piezoelectric film. In various embodiments, the acoustic waves are configured to drive the SQ transition via an alternating current (AC) strain in the diamond substrate. In various embodiments, the system further comprises a light source or a detector in optical communication with the NV center. In various embodiments, the light source or the detector is in optical communication with the NV center via a microscope objective. In various embodiments, the controller is further coupled with the light source or the detector and further configured to cause the light source to direct light to the NV center to thereby drive the NV center from a first electronic state to a second electronic state or to cause the detector to detect a fluorescence signal emitted by the NV center, the fluorescence signal indicative of a spin state of the NV center. In various embodiments, the system further comprises at least one magnet configured to introduce a Zeeman splitting between the first spin state and the second spin state. In various embodiments, the controller is further configured to cause the acoustic transducer to generate acoustic waves within the diamond substrate to sensitize the NV center to a magnetic field, electric field, strain, or temperature in a vicinity of the NV center.

In another aspect, the present disclosure provides a method comprising: generating acoustic waves within a diamond substrate comprising at least one NV center therein to thereby drive a single-quantum transition from a first spin state of the NV center to a second spin state of the NV center. In various embodiments, the first spin state comprises an mₛ=0 state and the second spin state comprises an mₛ=−1 state or an mₛ=+1 state. In various embodiments, the first spin state comprises an mₛ=−1 state or an mₛ=+1 state and the second spin state comprises an mₛ=0 state. In various embodiments, the acoustic waves are configured to drive the SQ transition via an alternating current (AC) strain in the diamond substrate. In various embodiments, the method further comprises directing light to the NV center to thereby drive the NV center from a first electronic state to a second electronic state. In various embodiments, the method further comprises detecting a fluorescence signal emitted by the NV center, the fluorescence signal indicative of a spin state of the NV center. In various embodiments, the method further comprises introducing a Zeeman splitting between the first spin state and the second spin state. In various embodiments, the method further comprises generating acoustic waves within the diamond substrate to sensitize the NV center to a magnetic field, electric field, strain, or temperature in a vicinity of the NV center.

### BRIEF DESCRIPTION OF THE DRAWINGS

FIG. 1 is a simplified exemplary diagram of a first system for acoustically driving a diamond NV center, in accordance with various embodiments.

FIG. 2 is a simplified exemplary diagram of a second system for acoustically driving a diamond NV center, in accordance with various embodiments.

FIG. 3 shows a flowchart for a method for acoustically driving a diamond NV center, in accordance with various embodiments.

FIG. 4 is a block diagram of a computer-based system for acoustically driving a diamond NV center, in accordance with various embodiments.

FIG. 5 is a block diagram of a computer system, in accordance with various embodiments.

FIG. 6(a) shows ground state spin levels of an NV center as a function of axial magnetic field, in accordance with various embodiments.

FIG. 6(b) shows uni-axial stress along a diamond crystal axis, in accordance with various embodiments.

FIG. 6(c) shows a photoluminescence scan of a device described herein, in accordance with various embodiments.

FIG. 6(d) shows an electron spin resonance (ESR) signal of a device described herein, in accordance with various embodiments.

FIG. 6(e) shows a cross-sectional view of a device described herein, in accordance with various embodiments.

FIG. 6(f) shows a closeup of an area under study, in accordance with various embodiments.

FIG. 7(a) shows ground-state spin level diagrams of single-quantum (SQ) and double-quantum (DQ) transitions, in accordance with various embodiments.

FIG. 7(b) shows measurements of the total field probed by SQ ESR spectroscopy, in accordance with various embodiments.

FIG. 7(c) shows results from SQ Rabi spectroscopy near leads of an acoustic transducer described herein, in accordance with various embodiments.

FIG. 7(d) shows Fourier transforms of the data in FIG. 7(c), in accordance with various embodiments.

FIG. 7(e) shows results from SQ Rabi spectroscopy near the center of an acoustic transducer described herein, in accordance with various embodiments.

FIG. 7(f) shows Fourier transforms of the data in FIG. 7(e), in accordance with various embodiments.

FIG. 7(g) shows measurement of the total field probed by SQ Rabi spectroscopy, in accordance with various embodiments.

FIG. 7(h) shows Fourier transforms of the data in FIG. 7(g), in accordance with various embodiments.

FIG. 8(a) shows an amplitude response for a magnetic field produced by an equivalent circuit model of the device described herein, in accordance with various embodiments.

FIG. 8(b) shows a phase response for a magnetic field produced by an equivalent circuit model of the device described herein, in accordance with various embodiments.

FIG. 8(c) shows an amplitude response for an acoustic field produced by an equivalent circuit model of the device described herein, in accordance with various embodiments.

FIG. 8(d) shows a phase response for an acoustic field produced by an equivalent circuit model of the device described herein, in accordance with various embodiments.

FIG. 9(a) shows heatmaps of structural similarity index calculated from a quantum master equation simulation of a SQ spin transition, in accordance with various embodiments.

FIG. 9(b) shows simulated Rabi spectroscopy results from the quantum master equation simulation, in accordance with various embodiments.

FIG. 9(c) shows Fourier transforms of the data in FIG. 9(b), in accordance with various embodiments.

FIG. 10(a) shows the results of a quantum master equation simulation, in accordance with various embodiments.

FIG. 10(b) shows a line cut from the results of FIG. 10(a) for a resonance mode at 2.732 gigahertz (GHz), in accordance with various embodiments.

FIG. 10(c) shows a line cut from the results of FIG. 10(a) for a resonance mode at 3.132 GHz, in accordance with various embodiments.

In various embodiments, not all of the depicted components in each figure may be required, and various embodiments may include additional components not shown in a figure. Variations in the arrangement and type of the components may be made without departing from the scope of the subject disclosure. Additional components, different components, or fewer components may be utilized within the scope of the subject disclosure. In the figures, like numbers denote like elements.

### DETAILED DESCRIPTION

In the following description, specific details are set forth describing some embodiments of the present disclosure. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure.

This description illustrates inventive aspects and embodiments should not be taken as limiting. The claims define the protected inventions. Various changes may be made without departing from the spirit and scope of this description and the claims. In some examples, well-known structures and techniques have not been shown or described in detail in order not to obscure the inventions.

Throughout the specification, reference is made to theoretical explanations for the behaviors expected in the various embodiments presented. These descriptions and explanations are intended to assist in understanding of the behavior of the embodiments disclosed below. The explanations provided below are not intended to be limiting of the claimed inventions in any way. The claimed inventions are not limited by any of the scientific theories used to help explain the behavior of specific devices described below.

As used herein, the term “or” shall convey both disjunctive and conjunctive meanings. For example, the phrase “A or B” shall be interpreted to include element A alone, element B alone, and the combination of elements A and B.

Due to the large size and high power requirements of magnetic pulse transducers, there has been some interest in replacing such transducers with acoustic transducers, which may be smaller and have lower power requirements. However, conventional NV acoustic transducers require a magnetic field pulse to drive the NV center from the mₛ=0 initial spin state to an mₛ=−1 spin state or mₛ=+1 spin state. Such acoustic transducers then implement double-quantum (DQ) transitions from the mₛ=−1 spin state to the mₛ=+1 spin state, or vice versa. In order to read out the fluorescence signal, the NV centers must be driven back to the mₛ=0 spin state by another magnetic field pulse. Thus, conventional NV acoustic transducers have been fundamentally limited to driving DQ transitions and have required the presence of supplementary magnetic pulse transducers.

Described herein are systems and methods for acoustically driving spin rotations of diamond nitrogen-vacancy (NV) centers using acoustic transducers. The systems and methods generally operate by generating acoustic waves within a diamond substrate containing an NV center. The acoustic waves drive alternating current (AC) strain in the diamond at a frequency matching a spin transition frequency of the NV center. These acoustic waves drive spin transitions through phonon modes rather than through the magnetic dipole interactions exploited by pulsed magnetic fields. The acoustic waves may be used to drive single-quantum (SQ) transitions in the NV center, such as transitions between the mₛ=0 and mₛ=−1 spin states and transitions between the mₛ=0 and mₛ=+1 spin states. The disclosure, however, is not limited to these exemplary embodiments and applications or to the manner in which the exemplary embodiments and applications operate or are described herein.

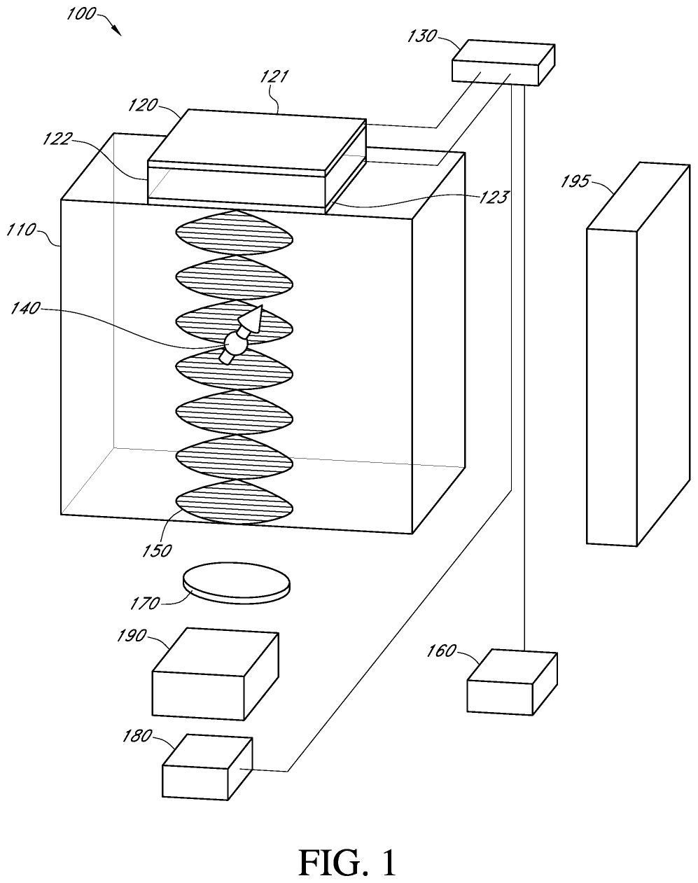

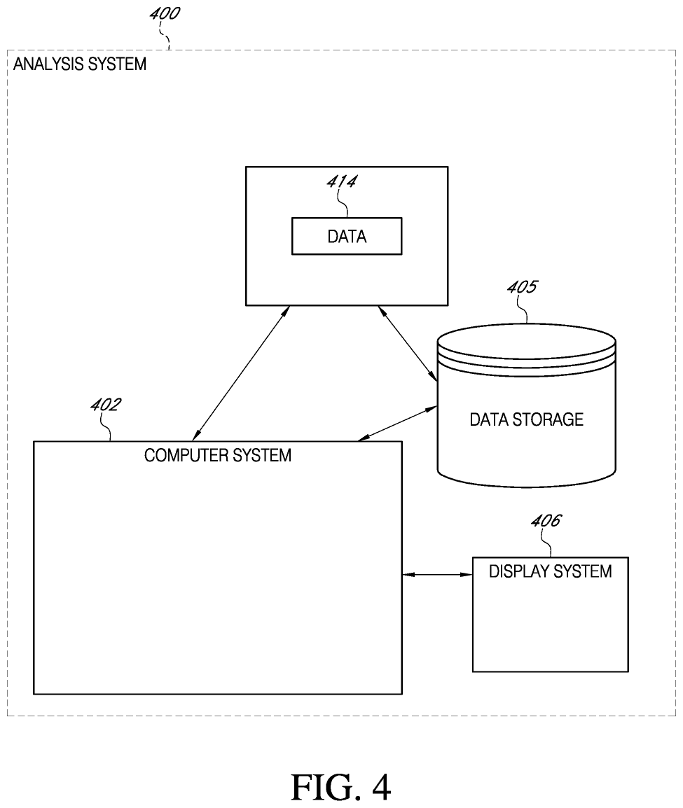

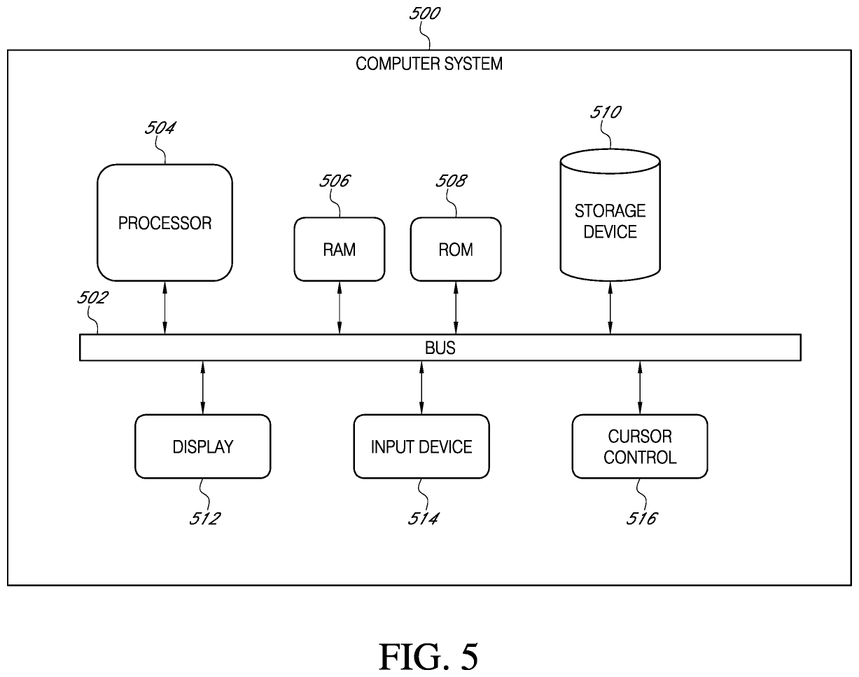

FIG. 1 is a simplified exemplary diagram of a first system 100 for acoustically driving a diamond NV center 140, in accordance with various embodiments. According to various embodiments, the system 100 may include a diamond substrate 110, an acoustic transducer 120 mechanically coupled to the diamond substrate 110, and a controller 130 coupled to the acoustic transducer 120. The diamond substrate 110 may include at least one NV center 140 therein. The controller 130 may be configured to cause acoustic transducer 120 to generate acoustic waves 150 within the diamond substrate 110. The acoustic waves 150 may be configured to drive a SQ transition from a first spin state of the NV center 140 to a second spin state of the NV center 140. The first spin state may be an mₛ=0 state and the second spin state may be an mₛ=−1 state or an mₛ=+1 state. The first spin state may be an mₛ=−1 state or an mₛ=+1 state and the second spin state may be an mₛ=0 state. The acoustic waves 150 may be configured to drive the SQ transition via an AC strain in the diamond substrate 110. The controller 130 may include one or more elements of systems 400 or 500 described herein with respect to FIG. 4 and FIG. 5, respectively.

In accordance with various embodiments, the diamond substrate 110 may be fabricated using a variety of methods. For example, the diamond substrate 110 may be fabricated by high temperature, high pressure production methods or by chemical vapor deposition (CVD) methods. The diamond substrate 110 may be cut, planarized, or polished by mechanical or chemical methods. Nitrogen atoms may be added to the diamond substrate 110 using a variety of methods, such as ion implantation or other ion doping techniques. Vacancies may be added to the diamond substrate 110 using a variety of methods, such as gamma ray bombardment methods. NV centers 140 may be formed by high-temperature annealing of the diamond substrate 110 following addition of the nitrogen atoms and vacancies.

In accordance with various embodiments, the diamond substrate 110 (or a portion thereof) may include any number of NV centers 140. For example, the diamond substrate 110 (or portion thereof) may include at least about 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more NV centers 140. The diamond substrate 110 (or portion thereof) may include at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 NV centers 140. The diamond substrate 110 (or portion thereof) may include a number of NV centers 140 that is within a range defined by any two of the preceding values. For example, the diamond substrate 110 (or portion thereof) may include between 1 and 1,000,000, between 1 and 100,000, between 1 and 10,000, between 1 and 1,000, between 1 and 100, between 1 and 10, between 10 and 1,000,000, between 10 and 100,000, between 10 and 10,000, between 10 and 1,000, between 10 and 100, between 100 and 1,000,000, between 100 and 100,000, between 100 and 10,000, between 100 and 1,000, between 1,000 and 1,000,000, between 1,000 and 100,000, between 1,000 and 10,000, between 10,000 and 1,000,000, between 10,000 and 100,000, or between 100,000 and 1,000,000 NV centers 140.

In accordance with various embodiments, the diamond substrate 110 (or portion thereof) may include any NV center density. For example, the diamond substrate 110 (or portion thereof) may include an NV center density of at least about 1 NV center 140 per cubic micrometer (μm⁻³), 2 μm⁻³, 3 μm⁻³, 4 μm⁻³, 5 μm⁻³, 6 μm⁻³, 7 μm⁻³, 8 μm⁻³, 9 μm⁻³, 10 μm⁻³, 20 μm⁻³, 30 μm⁻³, 40 μm⁻³, 50 μm⁻³, 60 μm⁻³, 70 μm⁻³, 80 μm⁻³, 90 μm⁻³, 100 μm⁻³, 200 μm⁻³, 300 μm⁻³, 400 μm⁻³, 500 μm⁻³, 600 μm⁻³, 700 μm⁻³, 800 μm⁻³, 900 μm⁻³, 1,000 m⁻³, or more. The diamond substrate 110 (or portion thereof) may include an NV center density of at most about 1,000 μm⁻³, 900 μm⁻³, 800 μm⁻³, 700 μm⁻³, 600 μm⁻³, 500 μm⁻³, 400 μm⁻³, 300 μm⁻³, 200 μm⁻³, 100 μm⁻³, 90 μm⁻³, 80 μm⁻³, 70 μm⁻³, 60 μm⁻³, 50 μm⁻³, 40 μm⁻³, 30 μm⁻³, 20 μm⁻³, 10 μm⁻³, 9 μm⁻³, 8 μm⁻³, 7 μm⁻³, 6 μm⁻³, 5 μm⁻³, 4 μm⁻³, 3 μm⁻³, 2 μm⁻³, 1 μm⁻³, or less. The diamond substrate 110 (or portion thereof) may include an NV center density that is within a range defined by any two of the preceding values. For example, the diamond substrate 110 (or portion thereof) may include an NV center density between 1 μm⁻³ and 1,000,000 μm⁻³, between 1 μm⁻³ and 100,000 μm⁻³, between 1 μm⁻³ and 10,000 μm⁻³, between 1 μm⁻³ and 1,000 μm⁻³, between 1 μm⁻³ and 100 μm⁻³, between 1 μm⁻³ and 10 μm⁻³, between 10 μm⁻³ and 1,000,000 μm⁻³, between 10 μm⁻³ and 100,000 μm⁻³, between 10 μm⁻³ and 10,000 μm⁻³, between 10 μm⁻³ and 1,000 μm⁻³, between 10 μm⁻³ and 100 μm⁻³, between 100 μm⁻³ and 1,000,000 μm⁻³, between 100 μm⁻³ and 100,000 μm⁻³, between 100 μm⁻³ and 10,000 μm⁻³, between 100 μm⁻³ and 1,000 μm⁻³, between 1,000 μm⁻³ and 1,000,000 μm⁻³, between 1,000 μm⁻³ and 100,000 μm⁻³, between 1,000 μm⁻³ and 10,000 μm⁻³, between 10,000 μm⁻³ and 1,000,000 μm⁻³, between 10,000 μm⁻³ and 100,000 μm⁻³, or between 100,000 μm⁻³ and 1,000,000 μm⁻³.

In accordance with various embodiments, the acoustic transducer 120 may comprise an acoustic resonator. The acoustic transducer may comprise a piezoelectric transducer that includes at least two electrodes. The acoustic transducer may be a bulk acoustic resonator (BAR), high-overtone BAR (HBAR), or semi-confocal HBAR (SCHBAR). For example, the acoustic transducer 120 may be similar to the SCHBARs described in H. Chen et al, “Engineering electron-phonon coupling of quantum defects to a semiconfocal acoustic resonator,” Nano Letters 19(10), 7021-7027 (2019), https://doi.org/10.1021/acs.nanolett.9b02430, which is entirely incorporated herein by reference for all purposes. The acoustic transducer 120 may be adhered to the diamond substrate 110. The acoustic transducer 120 may include a first thin metallic film 123 adhered to the diamond substrate 110, a piezoelectric film 122 adhered to the first thin metallic film 123, and a second thin metallic film 121 adhered to the piezoelectric film 122. The first or second thin metallic films 123 and 121 may include any metal, such as aluminum, copper, silver, gold, platinum, or any alloy thereof. The piezoelectric film 122 may include any piezoelectric material, such as, for example, langasite, gallium orthophosphate, lithium niobite, lithium tantalate, quartz, lead titanate, lead zirconate titanate, potassium niobate, sodium tungstate, barium sodium niobate, lead potassium niobate, zinc oxide, sodium potassium niobate, bismuth ferrite, sodium niobate, barium titanate, bismuth titanate, sodium bismuth titanate, polyvinylidene fluoride, polyvinylidene chloride, parylene, a III-V semiconductor, or a II-IV semiconductor.

The first or second thin metallic films may have a thickness of at least about 0.1 nanometers (nm), 0.2 nm, 0.3 nm, 0.4 nm, 0.5 nm, 0.6 nm, 0.7 nm, 0.8 nm, 0.9 nm, 1 nm, 2 nm, 3 nm, 4 nm, 5 nm, 6 nm, 7 nm, 8 nm, 9 nm, 10 nm, or more. The first or second thin metallic films may have a thickness of at most about 10 nm, 9 nm, 8 nm, 7 nm, 6 nm, 5 nm, 4 nm, 3 nm, 2 nm, 1 nm, 0.9 nm, 0.8 nm, 0.7 nm, 0.6 nm, 0.5 nm, 0.4 nm, 0.3 nm, 0.2 nm, 0.1 nm, or less. The first or second thin metallic films 123 and 121 may have a thickness that is within a range defined by any of the preceding values. For example, the first or second thin metallic films 123 and 121 may have a thickness between 0.1 nm and 10 nm, between 0.1 nm and 1 nm, or between 1 nm and 10 nm.

The first or second thin metallic films 123 and 121 may be deposited onto the diamond substrate 110 using a variety of physical or chemical deposition methods. For example, the first or second thin metallic films 123 and 121 may be deposited, for example, by vacuum thermal evaporation, electron beam evaporation, laser evaporation, arc evaporation, molecular beam epitaxy, ion plating evaporation, sputtering, direct current (DC) sputtering, radio-frequency (RF) sputtering, sol-gel methods, chemical bath deposition, spray pyrolysis, plating, electroplating, electroless deposition, CVD, low-pressure CVD (LPCVD), plasma-enhanced CVD (PECVD), or atomic layer deposition (ALD). The first or second thin metallic films 123 and 121 may be patterned using photolithography following by a variety of etching methods, such as, for example, wet chemical etching, anisotropic wet chemical etching, plasma etching, reactive ion etching (RIE), or deep RIE (DRIE).

The piezoelectric film 122 may have a thickness of at least about 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 micrometer (μm), 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, or more. The first or second thin metallic films may have a thickness of at most about 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, 90 nm, 80 nm, 70 nm, 60 nm, 50 nm, 40 nm, 30 nm, 20 nm, 10 nm, or less. The piezoelectric film 122 may have a thickness that is within a range defined by any of the preceding values. For example, the piezoelectric film 122 have may a thickness of between 10 nm and 100 μm, between 10 nm and 10 μm, between 10 nm and 1 μm, between 10 nm and 100 nm, between 100 nm and 100 μm, between 100 nm and 10 μm, between 100 nm and 1 μm, between 1 μm and 100 μm, between 1 μm and 10 μm, or between 10 μm and 100 μm.

The piezoelectric film 122 may be deposited onto the diamond substrate 110 using a variety of physical or chemical deposition methods. For example, the piezoelectric film 122 may be deposited, for example, by vacuum thermal evaporation, electron beam evaporation, laser evaporation, arc evaporation, molecular beam epitaxy, ion plating evaporation, sputtering, DC sputtering, RF sputtering, sol-gel methods, chemical bath deposition, spray pyrolysis, plating, electroplating, electroless deposition, CVD, LPCVD, PECVD, or ALD. The piezoelectric film 122 may be patterned using photolithography following by a variety of etching methods, such as wet chemical etching, anisotropic wet chemical etching, plasma etching, RIE, or DRIE.

In accordance with various embodiments, the acoustic transducer 120 may be configured to apply acoustic pulses having any energy. For example, the acoustic transducer 120 may be configured to apply acoustic pulses having an energy of at least about 1 picojoule (pJ), 2 pJ, 3 pJ, 4 pJ, 5 pJ, 6 pJ, 7 pJ, 8 pJ, 9 pJ, 10 pJ, 20 pJ, 30 pJ, 40 pJ, 50 pJ, 60 pJ, 70 pJ, 80 pJ, 90 pJ, 100 pJ, 200 pJ, 300 pJ, 400 pJ, 500 pJ, 600 pJ, 700 pJ, 800 pJ, 900 pJ, 1 nanojoule (nJ), 2 nJ, 3 nJ, 4 nJ, 5 nJ, 6 nJ, 7 nJ, 8 nJ, 9 nJ, 10 nJ, 20 nJ, 30 nJ, 40 nJ, 50 nJ, 60 nJ, 70 nJ, 80 nJ, 90 nJ, 100 nJ, 200 nJ, 300 nJ, 400 nJ, 500 nJ, 600 nJ, 700 nJ, 800 nJ, 900 nJ, 1,000 nJ, or more to achieve a π rotation of the spin state. The acoustic transducer 120 may be configured to apply acoustic pulses having an energy of at most about 1,000 nJ, 900 nJ, 800 nJ, 700 nJ, 600 nJ, 500 nJ, 400 nJ, 300 nJ, 200 nJ, 100 nJ, 90 nJ, 80 nJ, 70 nJ, 60 nJ, 50 nJ, 40 nJ, 30 nJ, 20 nJ, 10 nJ, 9 nJ, 8 nJ, 7 nJ, 6 nJ, 5 nJ, 4 nJ, 3 nJ, 2 nJ, 1 nJ, 900 pJ, 800 pJ, 700 pJ, 600 pJ, 500 pJ, 400 pJ, 300 pJ, 200 pJ, 100 pJ, 90 pJ, 80 pJ, 70 pJ, 60 pJ, 50 pJ, 40 pJ, 30 pJ, 20 pJ, 10 pJ, 9 pJ, 8 pJ, 7 pJ, 6 pJ, 5 pJ, 4 pJ, 3 pJ, 2 pJ, 1 pJ, or less to achieve a π rotation of the spin state. The acoustic transducer 120 may be configured to apply acoustic pulses having an energy that is within a range defined by any two of the preceding values to achieve a π rotation of the spin state. For example, the acoustic transducer 120 may be configured to apply acoustic pulses having an energy between 1 pJ and 1,000 nJ, between 1 pJ and 100 nJ, between 1 pJ and 10 nJ, between 1 pJ and 1 nJ, between 1 pJ and 100 pJ, between 1 pJ and 10 pJ, between 10 pJ and 1,000 nJ, between 10 pJ and 100 nJ, between 10 pJ and 10 nJ, between 10 pJ and 1 nJ, between 10 pJ and 100 pJ, between 100 pJ and 1,000 nJ, between 100 pJ and 100 nJ, between 100 pJ and 10 nJ, between 100 pJ and 1 nJ, between 1 nJ and 1,000 nJ, between 1 nJ and 100 nJ, between 1 nJ and 10 nJ, between 10 nJ and 1,000 nJ, between 10 nJ and 100 nJ, or between 100 nJ and 1,000 nJ to achieve a 7L rotation of the spin state.

In accordance with various embodiments, the acoustic transducer 120 may be characterized by any quality (Q) factor. For example, the acoustic transducer 120 may be characterized by a Q factor of at least about 100, 200, 300, 400, 500, 600, 700, 800, 900, 1,000, 2,000, 3,000, 4,000, 5,000, 6,000, 7,000, 8,000, 9,000, 10,000, or more. The acoustic transducer 120 may be characterized by a Q factor of at most about 10,000, 9,000, 8,000, 7,000, 6,000, 5,000, 4,000, 3,000, 2,000, 1,000, 900, 800, 700, 600, 500, 400, 300, 200, 100, or less. The acoustic transducer 120 may be characterized by a Q factor that is within a range defined by any two of the preceding values. For example, the acoustic transducer 120 may be characterized by a Q factor between 100 and 10,000, between 100 and 1,000, or between 1,000 and 10,000.

In accordance with various embodiments, the acoustic transducer 120 may have any characteristic size (such as a height, width, length, or radius). For example, the acoustic transducer 120 may have a characteristic size of at least about 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, 600 μm, 700 μm, 800 μm, 900 μm, 1,000 μm, or more. The acoustic transducer 120 may have a characteristic size of at most about 1,000 μm, 900 μm, 800 μm, 700 μm, 600 μm, 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, or less. The acoustic transducer 120 may have a characteristic size that is within a range defined by any two of the preceding values. For example, the acoustic transducer 120 may have a characteristic size between 1 μm and 1,000 μm, between 1 μm and 100 μm, between 1 μm and 10 μm, between 10 μm and 1,000 μm, between 10 μm and 100 μm, or between 100 μm and 1,000 μm.

In accordance with various embodiments, the acoustic waves 150 may include any frequency. For example, the acoustic waves 150 may include a frequency of at least about 1 gigahertz (GHz), 2 GHz, 3 GHz, 4 GHz, 5 GHz, 6 GHz, 7 GHz, 8 GHz, 9 GHz, 10 GHz, or more. The acoustic waves 150 may include a frequency of at most about 10 GHz, 9 GHz, 8 GHz, 7 GHz, 6 GHz, 5 GHz, 4 GHz, 3 GHz, 2 GHz, 1 GHz, or less. The acoustic waves 150 may include a frequency that is within a range defined by any two of the preceding values. For example, the acoustic waves 150 may include a frequency of between 1 GHz and 10 GHz.

In accordance with various embodiments, the system 100 may further include a light source 160 in optical communication with the NV center 140. The light source 160 may be a laser light source. The light source 160 may be configured to emit light having a wavelength of about 532 nm. The light source 160 may be coupled with the controller 130. The controller 130 may be further configured to cause the light source 160 to direct light to the NV center 140 to thereby drive the NV center 140 from a first electronic state to a second electronic state. The NV center 140 may then decay from the second electronic state to the mₛ=0 spin state.

In accordance with various embodiments, the light source 160 may be in optical communication with the NV center 140. The light source 160 may be in optical communication with the NV center 140 via a microscope objective 170. The microscope objective 170 may have a numerical aperture (NA) of at least about 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.05, 1.1, 1.15, 1.2, 1.25, 1.3, 1.35, 1.4, 1.45, 1.5, 1.55, 1.6, 1.65, 1.7, 1.75, 1.8, 1.85, 1.9, 1.95, 2, or more. The microscope objective 170 may have a NA of at most about 2, 1.95, 1.9, 1.85, 1.8, 1.75, 1.7, 1.65, 1.6, 1.55, 1.5, 1.45, 1.4, 1.35, 1.3, 1.25, 1.2, 1.15, 1.1, 1.05, 1, 0.95, 0.9, 0.85, 0.8, 0.75, 0.7, 0.65, 0.6, 0.55, 0.5, 0.45, 0.4, 0.35, 0.3, 0.25, 0.2, 0.15, 0.1, 0.05, or less. The microscope objective 170 may have a NA that is within a range defined by any two of the preceding values.

In accordance with various embodiments, the system 100 may further include a detector 180 in optical communication with the NV center 140. The detector 180 may be configured to detect a fluorescence signal emitted by the NV center 140. The fluorescence signal may be indicative of a spin state of the NV center 140. For example, the fluorescence signal may be indicative of a spin state of the NV center 140 directly prior to detection by the detector 180. The fluorescence signal may include a wavelength of at least about 625 nm, 630 nm, 635 nm, 640 nm, 645 nm, 650 nm, 655 nm, 670 nm, 675 nm, 680 nm, 685 nm, 690 nm, 695 nm, 700 nm, 705 nm, 710 nm, 715 nm, 720 nm, 725 nm, 730 nm, 735 nm, 740 nm, 745 nm, 750 nm, 755 nm, 760 nm, 765 nm, 770 nm, 775 nm, or more. The fluorescence signal may include a wavelength of at most about 775 nm, 770 nm, 765 nm, 760 nm, 755 nm, 750 nm, 745 nm, 740 nm, 735 nm, 730 nm, 725 nm, 720 nm, 715 nm, 710 nm, 705 nm, 700 nm, 695 nm, 690 nm, 685 nm, 680 nm, 675 nm, 670 nm, 665 nm, 660 nm, 655 nm, 650 nm, 645 nm, 640 nm, 635 nm, 630 nm, 625 nm, or less. The fluorescence signal may include a wavelength that is within a range determined by any two of the preceding values. For example, the fluorescence signal may include a wavelength between 625 nm and 775 nm. The fluorescence signal may be indicative of a projection of the spin state of the NV center 140 on the mₛ=0 state. An intensity of the fluorescence signal may be indicative of the projection of the spin state of the NV center 140 on the mₛ=0 state. The detector 180 may be in optical communication with the NV center 140. The detector 180 may be in optical communication with the NV center 140 via a microscope objective 170. In some cases, the system 100 may further include a dichroic beamsplitter 190, such as a dichroic filter or cold mirror. The dichroic beamsplitter 190 may be configured to reflect light from the light source 160 through the microscope objective 170 to the NV center 140 and configured to transmit the fluorescence signal from the NV center 140. Alternatively, the detector 180 may be in optical communication with the NV center 140 through a second microscope objective (not shown in FIG. 1).

In accordance with various embodiments, the system 100 may not include the microscope objective 170 or may not include the dichroic beamsplitter 190. The system 100 may be configured to allow edge detection, as described in D. Le Sage et al, “Efficient photon detection from color centers in a diamond optical waveguide,” Physical Review B 85, 121202 (2012), which is entirely incorporated herein by reference for all purposes. For example, the diamond substrate 110 may be fabricated such that the fluorescence signal is guided to one or more sides of the diamond substrate 110 by total internal reflection between an upper and lower surface of the diamond substrate. Such edge detection may reduce or eliminate the need for microscope objective 170 or dichroic beamsplitter 190.

In accordance with various embodiments, the system 100 may further include at least one magnet 195. The at least one magnet 195 may be configured to introduce a Zeeman splitting between the first spin state and the second spin state. The at least one magnet 195 may be a permanent magnet, bar magnet, single-sided magnet, electromagnetic, solenoid, Maxwell coil, two-axis Maxwell coil, three-axis Maxwell coil, Helmholtz coil, two-axis Helmholtz coil, three-axis Helmholtz coil, anti-Helmholtz coil, two-axis anti-Helmholtz coil, three-axis anti-Helmholtz coil, or superconducting magnet.

In accordance with various embodiments, the controller 130 may be further configured to cause the acoustic transducer 120 to generate acoustic waves 150 within the diamond substrate 110 to sensitize the NV center 140 to a magnetic field, electric field, strain, or temperature in a vicinity of the NV center 140. In some embodiments, the controller 130 may be configured to cause the acoustic transducer 120 to generate a pulse sequence of acoustic waves 150 within the diamond substrate 110 to sensitize the NV center 140 to the magnetic field, electric field, strain, or temperature. In some embodiments, the controller 130 may be further configured to cause the acoustic transducer 120 to generate acoustic waves 150 within the diamond substrate 110 to sensitize the NV center 140 to an orientation of the NV center 140. In some embodiments, the controller 130 may be configured to cause the acoustic transducer 120 to generate a pulse sequence of acoustic waves 150 within the diamond substrate 110 to sensitize the NV center 140 to the orientation of the NV center 140. The system 100 may thus operate as a magnetic field, electric field, orientation, strain, or temperature sensor. The acoustic pulse sequence may be similar to a magnetic pulse sequence disclosed in any of L. Pham, “Magnetic field sensing with nitrogen-vacancy color centers in diamond,” doctoral dissertation, Harvard University (2013), http://nrs.harvard.edu/um-3:HUL:InstRepos:11051173; F. Dolde et al, “Electric-field sensing using single diamond spins,” Nature Physics 7, 459-463 (2011), https://doi.org/10.1038/nphys1969; B. J. Maertz et al, “Vector magnetic field microscopy using nitrogen vacancy centers in diamond,” Applied Physics Letters 96, 092504 (2010), https://doi.org/10.1063/1.3337096; F. Grazioso et al, “Measurement of the full stress tensor in a crystal using photoluminescence from point defects: the example of nitrogen vacancy centers in diamond,” Applied Physics Letters 103, 101905 (2013), https://doi.org/10.1063/1.4819834; and A. Laraoui et al, “Imaging thermal conductivity with nanoscale resolution using a scanning spin probe,” Nature Communications 6, 8954 (2015), https://doi.org/10.1038/ncomms9954, each of which is entirely incorporated herein by reference for all purposes.

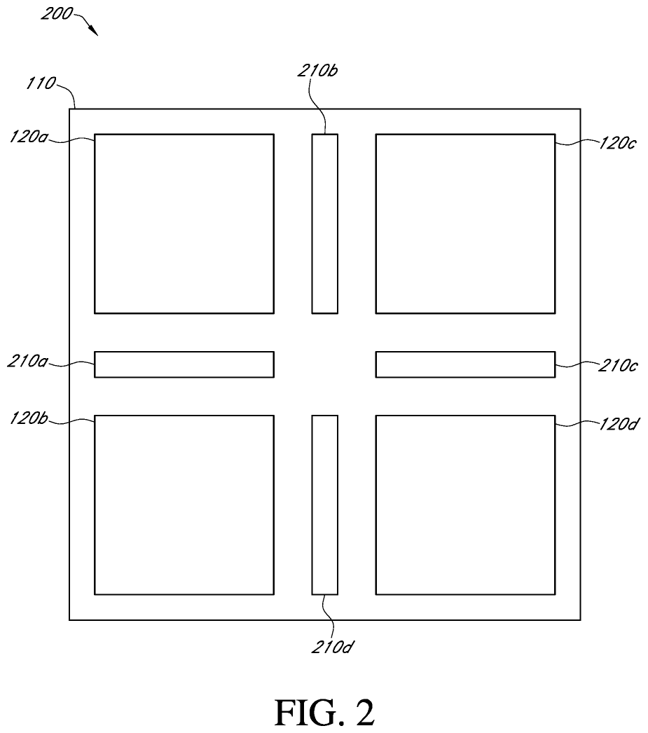

FIG. 2 is a simplified exemplary diagram of a second system 200 for acoustically driving a diamond NV center 140, in accordance with various embodiments. According to various embodiments, the system 200 may include a diamond substrate 110. The system 200 may include a plurality of acoustic transducers 120. For example, the system may include first acoustic transducer 120a, second acoustic transducer 120b, third acoustic transducer 120c, and fourth acoustic transducer 120d, each of which may be similar to any acoustic transducer 120 described herein. The system 200 may further include a controller 130, a plurality of NV centers 140, a light source 160, a microscope objective 170, a detector 180, a dichroic beamsplitter 190, or a magnet 195 (none of which are shown in FIG. 2), as described herein.

In accordance with various embodiments, the system 200 may include any number of acoustic transducers 120. For example, the system 200 may include at least about 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more acoustic transducers 120. The system 200 may include at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 acoustic transducers 120. The system 200 may include a number of acoustic transducers 120 that is within a range defined by any two of the preceding values. For example, the system 200 may include between 1 and 1,000,000, between 1 and 100,000, between 1 and 10,000, between 1 and 1,000, between 10 and 1,000,000, between 10 and 100,000, between 10 and 10,000, between 10 and 1,000, between 100 and 1,000,000, between 100 and 100,000, between 100 and 10,000, between 100 and 1,000, between 1,000 and 1,000,000, between 1,000 and 100,000, between 1,000 and 10,000, between 10,000 and 1,000,000, between 10,000 and 100,000, or between 100,000 and 1,000,000 acoustic transducers 120.

In accordance with various embodiments, the system 200 may include any acoustic transducer density. For example, the system 200 may include an acoustic transducer density of at least about 1 acoustic transducer 120 per square millimeter (mm⁻²) 2 mm⁻², 3 mm⁻², 4 mm⁻², 5 mm⁻², 6 mm⁻², 7 mm⁻², mm², 9 mm⁻² 10 mm⁻², 20 mm⁻², 30 mm⁻², 40 mm⁻², 50 mm⁻², 60 mm⁻², 70 mm⁻², 80 mm⁻², 90 mm⁻², 100 mm⁻², 200 mm⁻², 300 mm⁻², 400 mm⁻², 500 mm⁻², 600 mm⁻², 700 mm⁻², 800 mm⁻², 900 mm⁻², 1,000 mm⁻², or more. The system 200 may include an acoustic transducer density of at most about 1,000 mm⁻², 900 mm⁻², 800 mm⁻², 700 mm⁻², 600 mm⁻², 500 mm⁻², 400 mm⁻², 300 mm⁻², 200 mm⁻², 100 mm⁻², 90 mm⁻², 80 mm⁻², 70 mm⁻², 60 mm², 50 mm⁻², 40 mm⁻², 30 mm⁻², 20 mm⁻², 10 mm⁻², 9 mm⁻², 8 mm⁻², 7 mm⁻², 6 mm², 5 mm⁻², 4 mm⁻², 3 mm⁻², 2 mm⁻², 1 mm⁻², or less. The system 200 may include an acoustic transducer density that is within a range defined by any two of the preceding values. For example, the system 200 may include an acoustic transducer density between 1 mm⁻² and 1,000 mm⁻², between 1 mm⁻² and 100 mm⁻², between 1 mm⁻² and 10 mm⁻², between 10 and 1,000 mm⁻², between 10 mm⁻² and 100 mm⁻², or between 100 mm⁻² and 1,000 mm⁻². Each of the acoustic transducers 120 may be mechanically coupled to all or a portion of a surface of the diamond substrate 110.

In accordance with various embodiments, each acoustic transducer 120 may be configured to address any number of NV centers 140. For example, each acoustic transducer 120 may be configured to address at least about 1, 2, 3, 4, 5, 6, 7, 8, 9, 10, 20, 30, 40, 50, 60, 70, 80, 90, 100, 200, 300, 400, 500, 600, 700, 800, 900, 1,000, or more NV centers 140. Each acoustic transducer 120 may be configured to address at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 NV centers 140. For example, each acoustic transducer 120 may be configured to address between 1 and 1,000, between 1 and 100, between 1 and 10, between 10 and 1,000, between 10 and 100, or between 100 and 1,000 NV centers 140. Each acoustic transducer 120 may be configured to address a number of NV centers 140 that is within a range defined by any two of the preceding values. The number of NV centers 140 that each acoustic transducer 120 is configured to address may be determined by the number of NV centers 140 in proximity to the acoustic transducer 120.

In accordance with various embodiments, each acoustic transducer 120 may be mechanically isolated from cross-talk resulting from acoustic waves 150 emitted by other acoustic transducers 120. The acoustic transducers 120 may be mechanically isolated from cross-talk by, for example, a plurality of cuts in the diamond substrate 110. For example, the system 200 may include a first cut 210a, a second cut 210b, a third cut 210c, and a fourth cut 210d, as shown in FIG. 2. The plurality of cuts in the diamond substrate 110 may mechanically isolate a portion of the diamond substrate 110 that is in proximity to a given acoustic transducer 120 from other portions of the diamond substrate 110. In this manner, each acoustic transducer 120 may act independently on NV centers 140 located in its proximity.

In accordance with various embodiments, the system 200 may include any number of cuts in the diamond substrate 110. For example, the system 200 may include at least about 1, 2, 3, 4, 5, 6, 7, 8, 9, 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more cuts in the diamond substrate 110. The system 200 may include at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, 9, 8, 7, 6, 5, 4, 3, 2, or 1 cuts in the diamond substrate 110. The system 200 may include a number of cuts in the diamond substrate 110 that is within a range defined by any two of the preceding values. For example, the system 200 may include between 1 and 1,000,000, between 1 and 100,000, between 1 and 10,000, between 1 and 1,000, between 1 and 100, between 1 and 10, between 10 and 1,000,000, between 10 and 100,000, between 10 and 10,000, between 10 and 1,000, between 10 and 100, between 100 and 1,000,000, between 100 and 100,000, between 100 and 10,000, between 100 and 1,000, between 1,000 and 1,000,000, between 1,000 and 100,000, between 1,000 and 10,000, between 10,000 and 1,000,000, between 10,000 and 100,000, or between 100,000 and 1,000,000 cuts in the diamond substrate 110.

In accordance with various embodiments, each acoustic transducer 120 may be electromagnetically isolated from cross-talk resulting from electromagnetic waves emitted by other acoustic transducers 120.

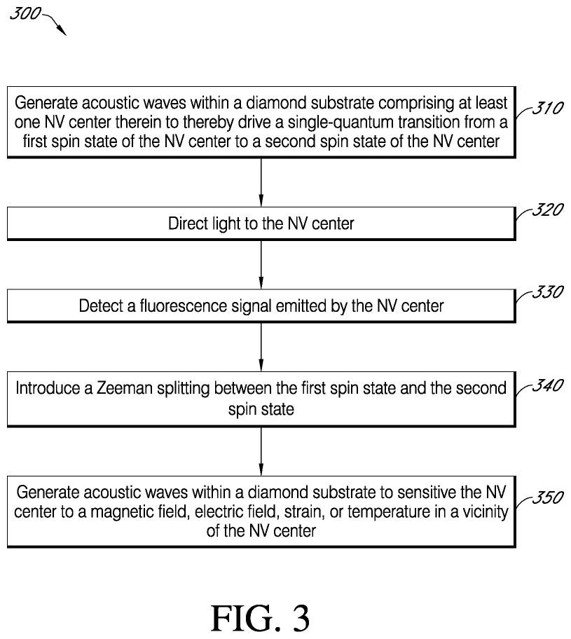

FIG. 3 shows a flowchart for a method 300 for acoustically driving a diamond NV center 140, in accordance with various embodiments. In various embodiments, the method 300 may v a first step 310 of generating acoustic waves 150 within a diamond substrate 110 comprising at least one NV center 140 therein to thereby drive a single-quantum transition from a first spin state of the NV center 140 to a second spin state of the NV center 140.

In various embodiments, the method 300 may include a second step 320 of directing light to the NV center 140 to thereby drive the NV center 140 from a first electronic state to a second electronic state.

In various embodiments, the method 300 may include a third step 330 of detecting a fluorescence signal emitted by the NV center 140. The fluorescence signal may be indicative of a spin state of the NV center 140.

In various embodiments, the method 300 may include a fourth step 340 of introducing a Zeeman splitting between the first spin state and the second spin state.

In various embodiments, the method 300 may include a fifth step 350 of generating acoustic waves 150 within the diamond substrate 110 to sensitize the NV center 140 to a magnetic field, electric field, strain, or temperature in a vicinity of the NV center 140.

The method 300, or any of steps 310, 320, 330, 340, and 350, may be implemented using any of the systems described herein, such as systems 100, 200, 400, or 500 described herein with respect to FIG. 1, FIG. 2, FIG. 4, and FIG. 5, respectively.

It should also be appreciated that any operation, sub-operation, step, sub-step, process, or sub-process of method 300 may be performed in an order or arrangement different from the embodiments illustrated by FIG. 3. For example, in other embodiments, one or more operations may be omitted or added.

In various embodiments, at least a portion of the methods for acoustically driving a diamond NV center 140 can be implemented via software, hardware, firmware, or a combination thereof.

That is, as depicted in FIG. 4, the methods and systems disclosed herein can be implemented on a computer-based system 400 for acoustically driving a diamond NV center 140. The system 400 may include a computer system such as computer system 402 (e.g., a computing device/analytics server). In various embodiments, the computer system 402 can be communicatively connected to a data storage 405 and a display system 406 via a direct connection or through a network connection (e.g., LAN, WAN, Internet, etc.). The computer system 402 can be configured to receive data, such as image feature data described herein. It should be appreciated that the computer system 402 depicted in FIG. 4 can include additional engines or components as needed by the particular application or system architecture.

FIG. 5 is a block diagram of a computer system 500, in accordance with various embodiments. Computer system 500 may be an example of one implementation for computer system 402 described herein with respect to FIG. 4. In one or more examples, computer system 500 can include a bus 502 or other communication mechanism for communicating information, and a processor 504 coupled with bus 502 for processing information. In various embodiments, computer system 500 can also include a memory, which can be a random-access memory (RAM) 506 or other dynamic storage device, coupled to bus 502 for determining instructions to be executed by processor 504. Memory also can be used for storing temporary variables or other intermediate information during execution of instructions to be executed by processor 504. In various embodiments, computer system 500 can further include a read only memory (ROM) 508 or other static storage device coupled to bus 502 for storing static information and instructions for processor 504. A storage device 510, such as a magnetic disk or optical disk, can be provided and coupled to bus 502 for storing information and instructions.

In various embodiments, computer system 500 can be coupled via bus 502 to a display 512, such as a cathode ray tube (CRT) or liquid crystal display (LCD), for displaying information to a computer user. An input device 514, including alphanumeric and other keys, can be coupled to bus 502 for communicating information and command selections to processor 504. Another type of user input device is a cursor control 516, such as a mouse, a joystick, a trackball, a gesture input device, a gaze-based input device, or cursor direction keys for communicating direction information and command selections to processor 504 and for controlling cursor movement on display 512. This input device 514 typically has two degrees of freedom in two axes, a first axis (e.g., x) and a second axis (e.g., y), that allows the device to specify positions in a plane. However, it should be understood that input devices 514 allowing for three-dimensional (e.g., x, y and z) cursor movement are also contemplated herein.

Consistent with certain implementations of the present teachings, results can be provided by computer system 500 in response to processor 504 executing one or more sequences of one or more instructions contained in RAM 506. Such instructions can be read into RAM 506 from another computer-readable medium or computer-readable storage medium, such as storage device 510. Execution of the sequences of instructions contained in RAM 506 can cause processor 504 to perform the processes described herein. Alternatively, hard-wired circuitry can be used in place of or in combination with software instructions to implement the present teachings. Thus, implementations of the present teachings are not limited to any specific combination of hardware circuitry and software.

The term “computer-readable medium” (e.g., data store, data storage, storage device, data storage device, etc.) or “computer-readable storage medium” as used herein refers to any media that participates in providing instructions to processor 504 for execution. Such a medium can take many forms, including but not limited to, non-volatile media, volatile media, and transmission media. Examples of non-volatile media can include, but are not limited to, optical, solid state, magnetic disks, such as storage device 510. Examples of volatile media can include, but are not limited to, dynamic memory, such as RAM 506. Examples of transmission media can include, but are not limited to, coaxial cables, copper wire, and fiber optics, including the wires that make up bus 502.

Common forms of computer-readable media include, for example, a floppy disk, a flexible disk, hard disk, magnetic tape, or any other magnetic medium, a CD-ROM, any other optical medium, punch cards, paper tape, any other physical medium with patterns of holes, a RAM, PROM, and EPROM, a FLASH-EPROM, any other memory chip or cartridge, or any other tangible medium from which a computer can read.

In addition to computer readable medium, instructions or data can be provided as signals on transmission media included in a communications apparatus or system to provide sequences of one or more instructions to processor 504 of computer system 500 for execution. For example, a communication apparatus may include a transceiver having signals indicative of instructions and data. The instructions and data are configured to cause one or more processors to implement the functions outlined in the disclosure herein. Representative examples of data communications transmission connections can include, but are not limited to, telephone modem connections, wide area networks (WAN), local area networks (LAN), infrared data connections, NFC connections, optical communications connections, etc.

It should be appreciated that the methodologies described herein, flow charts, diagrams, and accompanying disclosure can be implemented using computer system 500 as a standalone device or on a distributed network of shared computer processing resources such as a cloud computing network.

The methodologies described herein may be implemented by various means depending upon the application. For example, these methodologies may be implemented in hardware, firmware, software, or any combination thereof. For a hardware implementation, the processing unit may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

In various embodiments, the methods of the present teachings may be implemented as firmware and/or a software program and applications written in conventional programming languages such as C, C++, Python, etc. If implemented as firmware and/or software, the embodiments described herein can be implemented on a non-transitory computer-readable medium in which a program is stored for causing a computer to perform the methods described above. It should be understood that the various engines described herein can be provided on a computer system, such as computer system 500, whereby processor 504 would execute the analyses and determinations provided by these engines, subject to instructions provided by any one of, or a combination of, the memory components RAM 506, ROM 508, or storage device 510 and user input provided via input device 514.

### Examples

Quantification of acoustically-driven SQ spin transition is important because SQ acoustic driving can enable all-acoustic quantum control of the NV center electron spin, which can have impact in real-world sensing applications. Given that the solid-state phonon wavelength is 10⁴ shorter than that of a microwave photon at the same frequency, acoustic wave devices also support higher resolution, selective local spin control. Additionally, acoustic devices can be engineered with a smaller foot-print and with potentially lower power consumption. An experimental study of acoustically-driven SQ spin transitions of NV centers using a 3 GHz diamond bulk acoustic resonator device was conducted. The device converted a microwave driving voltage into an acoustic wave through a piezoelectric transducer, thus mechanically addressing the NV centers in the bulk diamond substrate. Because a microwave current flows through the device transducer, an oscillating magnetic field of the same frequency coexists with the stress field that couples to SQ spin transitions. To identify and quantify the mechanical contribution to the SQ spin transition, Rabi spectroscopy was used to separately quantify the magnetic and stress fields present in the device as a function of driving frequency. Based on these results, a theoretical model was conducted and SQ spin transition Rabi spectroscopy was simulated to compare to the experimental results. From a systematically identified closest match, the mechanical driving field contribution was calculated and the effective spin-stress susceptibility b′ was extracted. Measurements were performed on SQ spin transitions between both the mₛ=0 and mₛ=+1 spin states and between the mₛ=0 and mₛ=−1 spin states. The stress susceptibility was determined to be b′/b=\sqrt{2}(0.5±0.2), around an order of magnitude larger than predicted by theory.

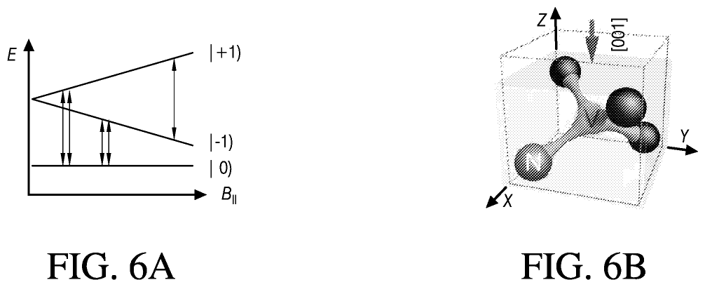

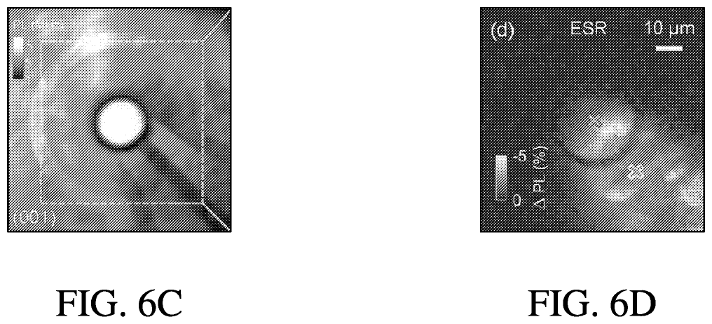

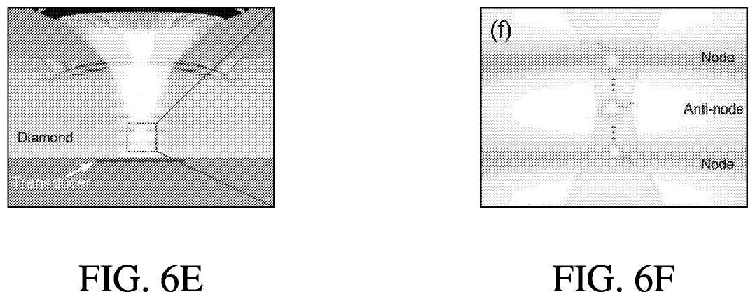

The ground state electron spin of an NV center can be described by the Hamiltonian Hₑ/h=S_{z}²+γₑB·S+H_{σ}/h, where h is the Planck constant, D=2.87 GHz is the zero field splitting, S=(Sₓ, S_{y}, S_{z}) is the vector of spin-1 Pauli matrices, γₑ=2.802 MHz/G is the spin gyromagnetic ratio in response to an external magnetic field, B=(Bₓ, B_{y}, B_{z}). H_{σ} contains the electron spin-stress interaction. As shown in FIG. 6(a), in the presence of an external magnetic field aligned along NV axis, the mₛ=−1 and mₛ=1 levels split linearly with the magnetic field amplitude due to the Zeeman effect. This gives rise to three sets of qubits of two types: 1) (mₛ=0, mₛ=+1) and (mₛ=0, mₛ=−1) operated on a SQ transition; 2) (mₛ=+1, mₛ=−1) operated on the DQ transition. While the magnetic dipole transition is only accessible for SQ transitions, phonons can drive both SQ and DQ transitions.

Uni-axial stress fields σ_{ZZ} were generated along the [001] diamond crystal direction, as shown in FIG. 6(b)). This induces normal strain in the crystal,

$$\{ {ε}_{X X} , {ε}_{Y Y} , {ε}_{Z Z} \} = \frac{1}{E} \{ - v {σ}_{ZZ} , - v {εσ}_{ZZ} , {σ}_{Z Z} \} ,$$

where E is Young's modulus and v is Poisson's ratio. For simplicity, work is conducted in the stress frame and the following stress Hamiltonian applies: H_{σ}=H_{σ0}+H_{σ1}+H_{σ2}, where H_{σ0}/h=a₁σ_{ZZ}S_{z}², H_{σ1}/h=2b′σ_{ZZ}{Sₓ, S_{z}}, H_{σ2}/h=2bσ_{ZZ}(S_{y}²−Sₓ²), and a₁, b′, and b are stress susceptibility coefficients. Experiments have determined that a₁=4.86±0.02 MHz/GPa and b=−2.3±0.3 MHz/GPa, but b′ had not been characterized but had been theoretically predicted. After applying the rotating wave approximation, the total Hamiltonian is:

$${H}_{e} = ( \begin{matrix}D + {γ}_{e} {B}_{∥} + {a}_{1} {σ}_{Z Z} & \frac{1}{2} {Ω}_{1}^{+} {e}^{- i ω t} & \frac{1}{2} {Ω}_{2} {e}^{- i ω t} \\ \frac{1}{2} {Ω}_{1}^{+} {e}^{- i ω t} & 0 & \frac{1}{2} {Ω}_{1}^{-} {e}^{- i ω t} \\ \frac{1}{2} {Ω}_{2} {e}^{- i ω t} & \frac{1}{2} {Ω}_{1}^{-} {e}^{- i ω t} & D - {γ}_{e} {B}_{∥} + {a}_{1} {σ}_{Z Z}\end{matrix} )$$

Here, ω=2πf is the driving field frequency, Ω₁^{±}=|Ω_{B}±Ω_{σ1}=2|γₑB_{⊥}·S±\sqrt{2}b′σ_{ZZ}| is the SQ transition Rabi field amplitude. Ω_{B} and Ω_{σ} are complex Rabi fields from transverse magnetic field in microwave driving B_{⊥} and acoustic wave field σ_{ZZ}, respectively. Ω₂=|Ω_{σ2}|=4bσ_{ZZ} represents the acoustically-driven DQ transition Rabi field amplitude.

Experimentally, a semi-confocal bulk acoustic resonator device was fabricated on a 20 μm thick optical grade diamond substrate [(001) face orientation, NV center density ˜2×10¹³ cm⁻³ to launch longitudinal acoustic waves along diamond [001] crystal axis at two mechanical resonance frequencies fᵣ=3.132 GHz and 2.732 GHz. This allows phonon driving of both SQ transitions as well as the DQ transition. At room temperature, a focused 532 nm laser (0.5 mW) was used to excite NV centers in the substrate and their fluorescence from phonon side bands (>675 nm) was collected using a home-built confocal microscope. A photoluminescence scan of the device on XY plane is shown in FIG. 6(c), featuring a micro mechanical resonator (center bright circular area) encircled by a microwave loop antenna (radius 50 μm). FIG. 6(e) shows a schematic of the cross-sectional view of the device. The NA=0.8 objective in the confocal microscope had a depth resolution around 2.8 μm inside diamond, which is comparable to half of the acoustic wavelength, and much smaller than that of the characteristic microwave magnetic field decay length.

Microwave driving of the piezoelectric transducer creates a bulk acoustic wave confined in the resonator and current-induced magnetic field throughout the device. On a spin resonance, the mixing of spin states yields decreased photoluminescence (PL) from the NV centers. The PL signal from the electron spin resonance (ESR) can thus be used to spatially map the current-induced magnetic field distribution in the device. In FIG. 6(d), the transducer was driving on-resonance using a 2.715 GHz microwave source. The ESR measurement delineates the current field flowing through the leads and the resonator area. The acoustic wave field, however, is present only inside the resonator, as shown in FIG. 6(e).

Given that the magnetic driving field and the acoustic driving field coexist in the resonator and they both couple to SQ spin transition, producing pure acoustically-driven SQ spin transitions for NV centers is not possible for the current device. The two field contributions can be separately quantified using independent measurements on the two fields. More explicitly, the Rabi amplitude of the current-induced magnetic field Ω_{B} inside the resonator is proportional to that outside the resonator due to current continuity and can be quantified by scaling the magnetic field βΩ′_{B} measured near the leads, where acoustic wave is absent. The scaling factor β can be experimentally determined off a mechanical resonance frequency where the acoustic field is near zero. Because only phonon driving and not magnetic driving couples to the DQ transition, the amplitude of the acoustic wave inside the resonator can be inferred by measuring the DQ transition Rabi field, which is proportional to Ω_{σ1}=aΩ_{σ2}=b′/(\sqrt{2}b)Ω_{σ2}.

The phase properties of the two vector fields and the associated complex Rabi fields are complicated and evolve with frequency. The effect on Ω₁^{±} depends on both resonator electromechanical characteristics and field spatial directions relative to NV atomic axis. The first part may be taken into account by determining an equivalent circuit of the device, and the second part by introducing an unknown constant parameter ϕ to describe the phase difference of the two fields led by a spatial factor. The total SQ Rabi field as a function of driving frequency f is then Ω₁^{±}(f)=|βΩ′_{B}(f)e^{iϕ}±aΩ_{σ2}(f), where Ω(f)=Ω(f)e^{iθ(f)}, and where θ(f) depends on resonator electromechanical characteristics.

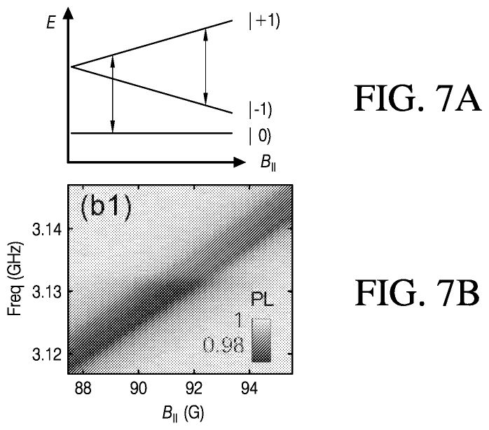

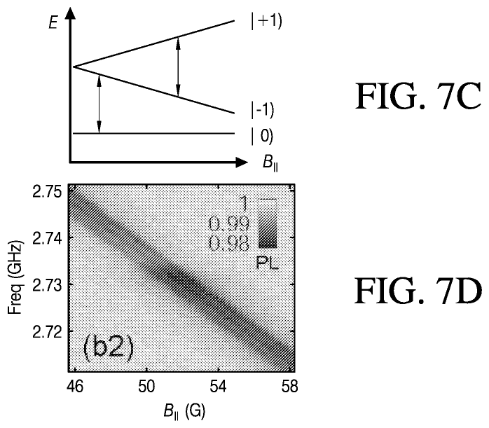

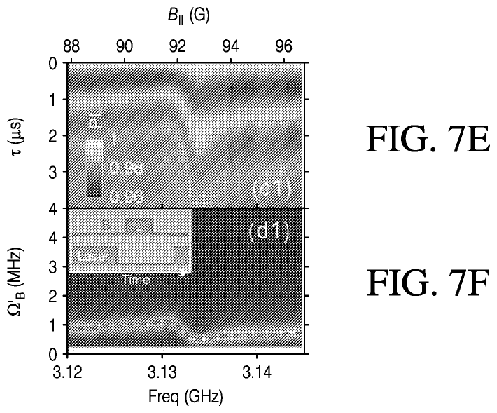

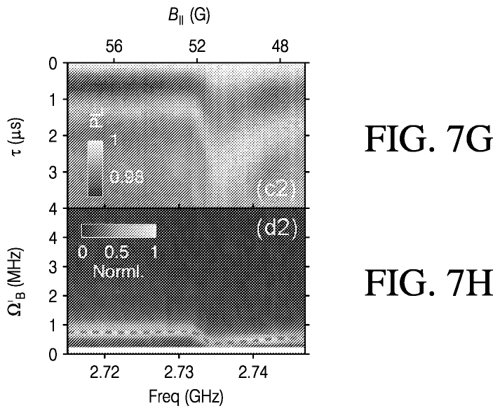

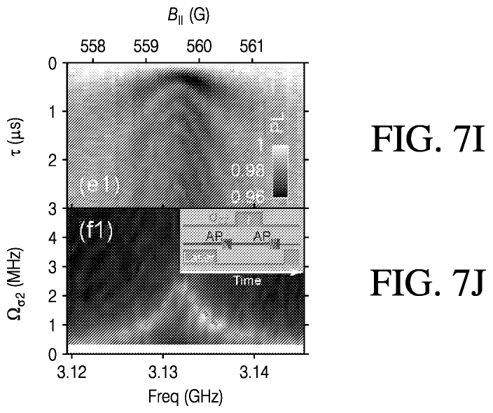

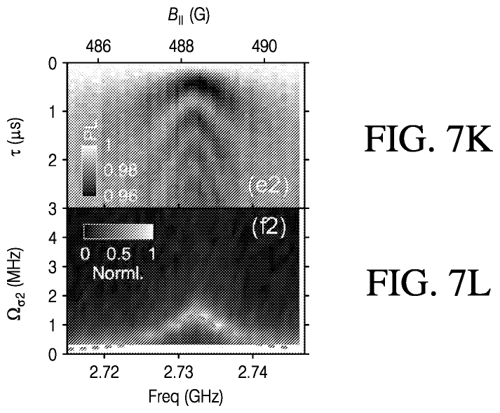

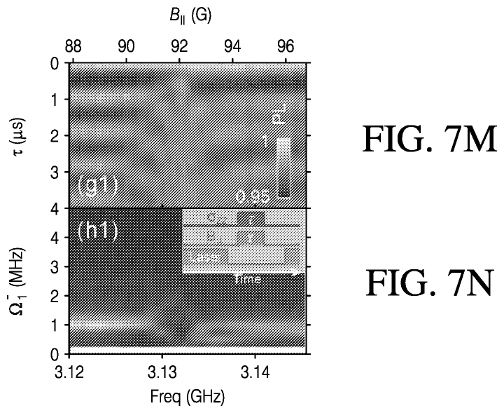

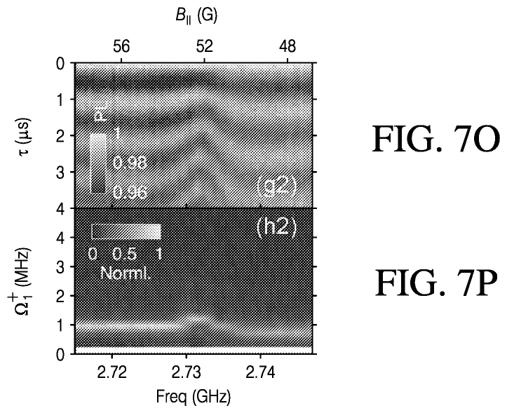

SQ NV center spin Rabi spectroscopy was used to measure Ω′_{B}(f) at the marked cross location in FIG. 6(d). The NV axial magnetic was varied around point where the SQ transition frequency is close to fᵣ, as shown in FIG. 6(a). At each value of B_{∥}, the driving frequency was adjusted to the Zeeman splitting to maintain a condition of on-resonance driving. After spin state initialization using optical spin polarization, Rabi oscillations were driven by applying varying length pulses to the piezoelectric transducer with a power at 10 dBm. The probed nuclear hyperfine levels were limited by requiring Ω′_{B}(f)<1.2 MHz, which is below the hyperfine coupling coefficient. The spin population's time evolution was then measured as a function of pulse duration through a photoluminescence measurement at the end of the Rabi sequence (inset in FIG. 7(b)). A series of measurements were done as B_{∥} and the corresponding resonant drive frequencies were varied around fᵣ. To ensure time stability, the probed location was tracked by active feedback to the objective position, and drift was limited in the probed volume to <(0.1 μm)³. The measurement results are shown in FIG. 7(c). Rabi frequencies can then be extracted from either fitting or by taking the peak Fourier component of the Rabi spectroscopy results, as shown in FIG. 7(d), and they are directly proportional to the associated driving field amplitude. By comparing the magnetically-driven Rabi fields that were measured off mechanical resonance frequency, β=1.30±0.01 was determined.

Similar Rabi spectroscopy was performed on the DQ transition to measure Ω_{σ2} at the marked cross location in FIG. 6(d) at a depth around 3 μm away from the transducer (as shown in FIG. 6(e)). From PL measurements of the NV center ensemble in comparison to the single NV center PL rate in the setup, around 150 (20) NV centers in the laser focal spot were, among which ˜35% of NV centers were aligned with the external magnetic field. As a result, there were 45-60 NV centers contributing to the signal, and they randomly spanned the node and anti-node of the acoustic wave, as shown in FIG. 7(f). The working axial magnetic field condition was close to the excited state level anti-crossing and provided near-perfect nuclear spin polarization. In each resonant Rabi driving sequence (inset in FIG. 7(f)), an adiabatic passage pulse was used to prepare all spins into mₛ=−−1 state. After resonant acoustic field driving, another adiabatic passage pulse was used to shelve the residual spin mₛ=−1 population into the mₛ=0 state prior to PL measurement. The results are shown in FIGS. 7(e)-(f).

For SQ Rabi spectroscopy of Ω′_{B}(f) measured at the leads, FIG. 7(d) shows two resonance features: the mechanical resonance at 3.132 GHz and an electrical anti-resonance at 3.134 GHz, which originate from the electromechanical coupling of the piezoelectric resonator. The result is consistent with the device admittance measurement using a vector network analyzer, and is used later towards the construction of a unique circuit model to describe the complex electromechanical response of the device. For DQ Rabi spectroscopy on Ω_{σ2}(f), FIG. 7(f) reveals a single Lorentzian mechanical resonance at 3.132 GHz, which corresponds to the longitudinal acoustic standing wave mode in the resonator. The modal mechanical quality factor Q can be directly calculated from the linewidth, which turns out to be around 1040 (40).

Having characterized the electromechanical response of the device, SQ Rabi spectroscopy was performed inside the resonator at the same location as the DQ measurement (marked cross location in FIG. 6(d)). The total Rabi field is complicated because the magnetic and acoustic fields jointly act on the transition, and the probed NV center ensemble includes NV centers coupled to both anti-node and node of the acoustic wave. The result shown in FIG. 7(d) is distinct from the previous single field measurements, and its Fourier transform in FIG. 7(h) disperses into multiple components due to the spatial inhomogeneity of stress coupling to the ensemble. To understand the spectrum and characterize the mechanical contribution to SQ spin transition, the experiment was modeled. Similar measurements were performed on a different acoustic mode at 2.732 GHz to probe the second SQ transition. The results for Ω′_{B}(f), Ω_{σ2}(f), and Ω₁⁻(f) are shown in FIGS. 7(c)-(h).

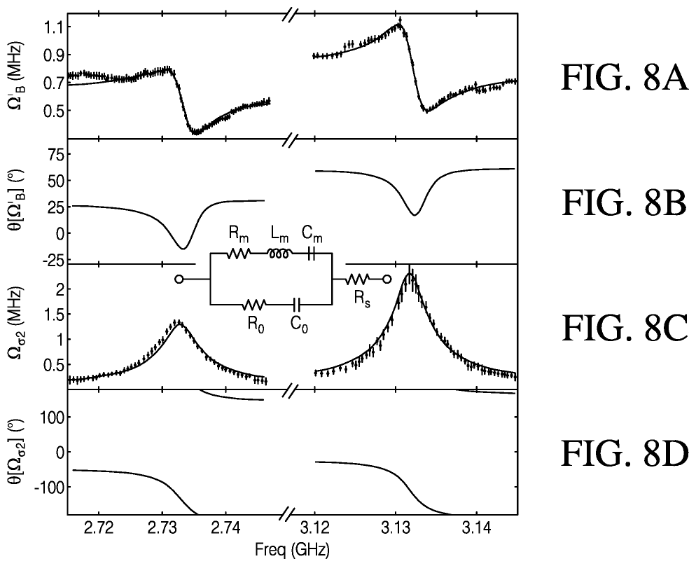

The electromechanical response of a piezoelectric resonator like the device described herein can be modeled using an electrical equivalent circuit known as the modified Butterworth-Van Dyke (mBVD) model. In the mBVD circuit model (FIG. 8 inset), the resonator acoustic mode is treated as a damped mechanical oscillator modeled using an electrical RₘLₘCₘ series circuit. The acoustic RₘLₘCₘ circuit is then parallelly coupled to an electrical R₀C₀ branch representing the electrical capacitance and dielectric loss in the transducer. Lastly, a serial resistor Rₛ is introduced to take into account ohmic loss in the contact lines. Applying an external voltage driving source near the resonance frequency fᵣ=1/(2π\sqrt{LₘCₘ}) can excite both current and acoustic fields in the circuit. More explicitly, the total current (or admittance Y) in the circuit model is proportional to the induced magnetic field, and the complex voltage value V across the capacitor Cₘ, is proportional to the stress field generated in the device.

With Ω′_{B}(f) and Ω′_{σ2}(f) measured experimentally, mBVD model fitting with all circuit parameters set free was performed using the following equations: Ω′_{B}(f)=A×|Y(Rₘ, Lₘ, Cₘ, R₀, C₀, Rₛ, f)| and Ω_{σ2}(f)=B×|V(Rₘ, Lₘ, Cₘ, R₀, C₀, Rₛ, f)|. The model fitting results are shown in FIG. 8, with the optimal fitting parameters as follows: A=235±155 MHz/S, B=2.6±0.1 kHz/V, Rₘ=219±165Ω, Lₘ=13±9 μH, Cₘ=0.20±0.14 fF, R₀=46±30Ω, 0.20±0.13 pF, and Rₛ=98±59Ω for the 3.132 GHz mode and A=624±74 MHz/S, B=4.9±0.2 kHz/V, Rₘ=69±20Ω, Lₘ=10±4 μH, Cₘ=0.33±0.13 fF, R₀=149±11 Ω, 0.13±0.05 pF, and Rₛ=732±86Ω for the 2.732 GHz mode. The large error bars are a result of the small covariance between the large number of fitting parameters, however, the model predictions of amplitude and phase are insensitive to these uncertainties. Thus the model accurately represents the physical phenomena and is suitable for the purposes herein. The unified circuit model not only reproduces the measured Rabi field amplitude, but also contains the requisite phase information. While the acoustic field goes through a 180 degree phase change across a single mechanical resonance, the current field undergoes two resonances, where the phase first drops around fᵣ and then increases around fₐ. From this analysis, full information of the complex Rabi field is obtained.

To interpret FIG. 7(g), evaluate a, and thus extract b′, a quantum master equation simulation was implemented as a function of driving frequency for an ensemble of six NV centers. The ensemble was treated as evenly distributed from an anti-node to a node of the acoustic wave, driven by the following SQ Rabi field Ω₁^{±}(f, z)=|1.3 Ω′_{B}(f)e^{iϕ}±aΩ_{σ2}(f)cos(kz)|, where k=2π/λ, λ=5.7 μm for the 3.132 GHz mode and 6.7 μm for the 2.732 GHz mode. The simulated time traces of spin population from each individual NV center were summed and averaged to construct the final simulated Rabi spectroscopy result.

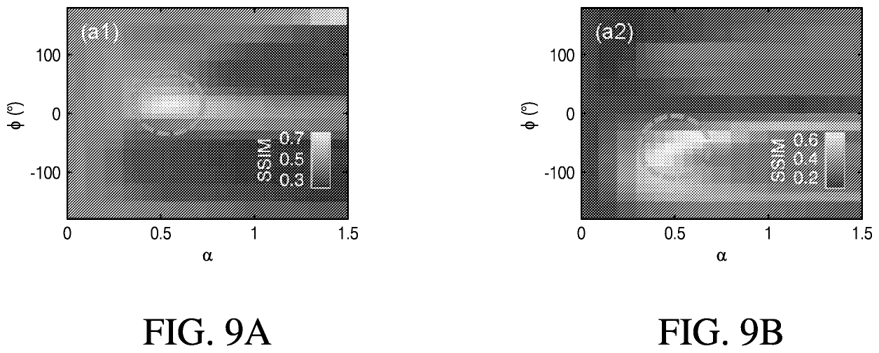

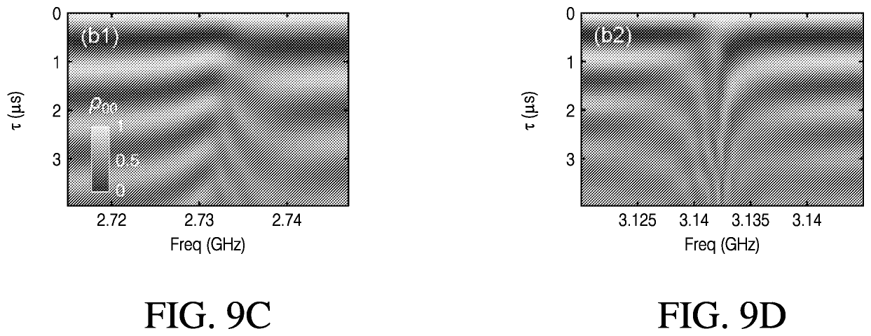

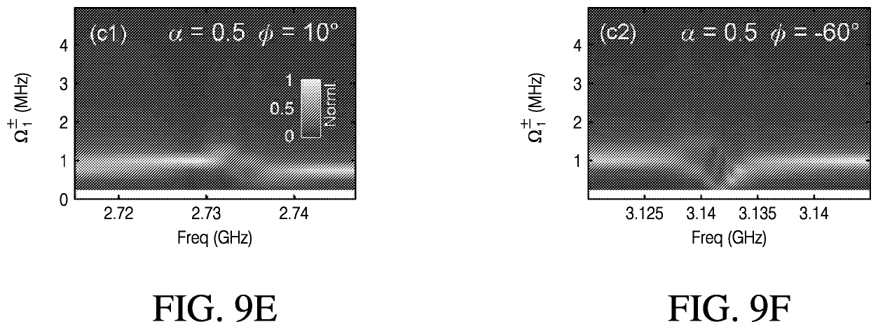

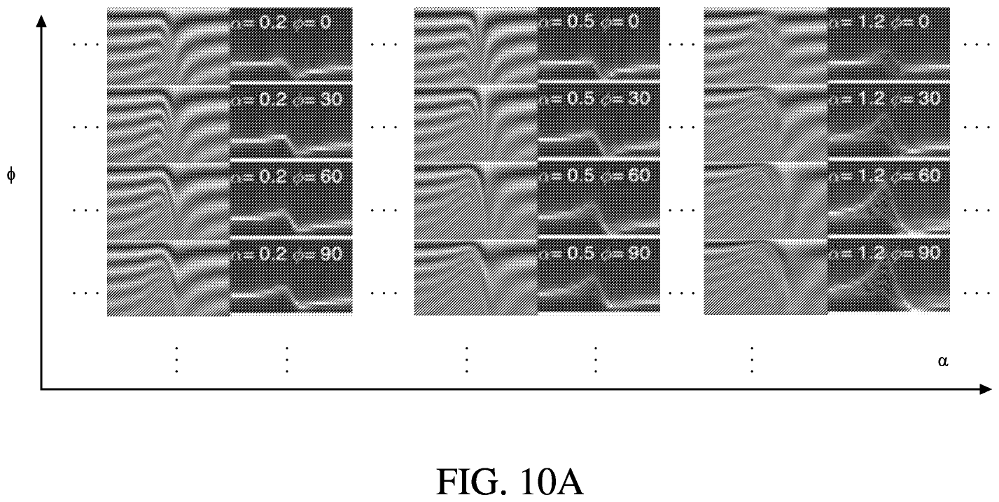

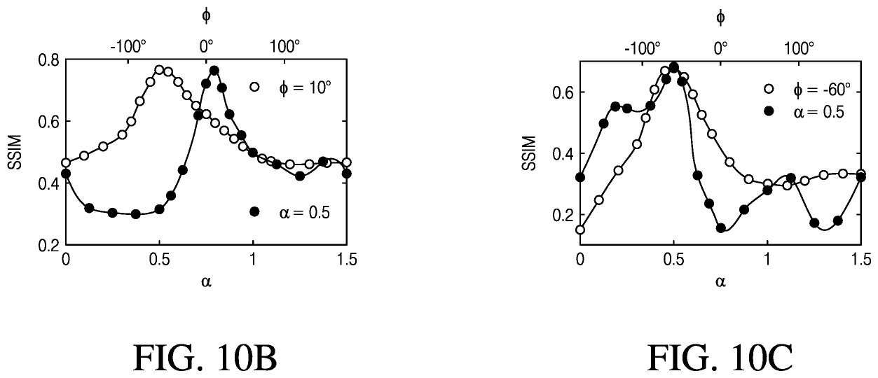

Simulations were implemented for a range of values and compared to the experimental data in FIG. 7(g) by calculating their structural similarity index (SSIM). The results are shown in FIG. 9(a). Higher SSIM value indicates better match of simulation to experiments. The best match was obtained at a=0.5±0.2 and ϕ=10°±40° for the 2.732 GHz mode and =0.5±0.2 and ϕ=−60°±60° for the 3.132 GHz mode. The corresponding simulated Rabi spectroscopy results are shown in FIG. 10(b), which agrees well with the experimental observation. Additionally, the same a result is obtained from both modes, which is expected physically. The difference in ϕ implies a phase change in electromechanical resonance or a direction change in magnetic vector field between the two resonance mode, which can be explained by the microwave resonance in the transmission line. From the result that a=b′/(\sqrt{2}b)=0.5±−0.2, it can be determined that the spin-stress susceptibility of the SQ transition compared to that of the DQ transition is b′/(\sqrt{2}b)=0.5±−0.2. This finding further completes the understanding of NV center ground state spin-stress Hamiltonian. Note that b′ describes spin coupling to only a normal stress field. The spin coupling to shear stress wave coefficient for SQ transition was not measured.

Numerical simulation of the experiment was performed using the Lindblad master equation,

$$\dot{ρ} = - \frac{i}{ℏ} \vert {H}_{e} , ρ \vert + {\sum }_{i , j} {γ}_{i j} ( {L}_{i} ρ {L}_{j}^{+} - \frac{1}{2} \{ {L}_{i}^{+} {L}_{j} , ρ \} ,$$

where ρ is the density matrix of the spin states, L is the Lindblad operator, and i and j range over the allowed spin states. For the short time scope of 4 μs studied here, T₁ spin relaxation was ignored, and phase coherence was set to 2 μs. The density matrix was evolved from a pure state the spin population was calculated to simulate the PL signal collected in the experiment.

Because a and ϕ are unknown from direct experimental measurement, a series of simulations were performed in the range a=(0, 1.5) and ϕ=(−180°, 180°), as shown in FIG. 10(a), which can be directly compared to experiment. The evaluation of experiment-simulation match was through structural similarity (SSIM) index:

$$SSIM ( x , y ) = \frac{( 2 {μ}_{x} {μ}_{y} + {C}_{1} ) ( 2 {σ}_{x y} + {C}_{2} )}{( {μ}_{x}^{2} + {μ}_{y}^{2} + {C}_{1} ) ( {σ}_{x}^{2} + {σ}_{y}^{2} + {C}_{2} )} ,$$

where μₓ, μ_{y}, σₓ, σ_{y}, and σ_{xy} are the local means, standard deviations, and cross-variance for the two images, under comparison. C₁=C₂/9=(0.01 L)², where L=255 is the dynamic range value of the image. SSIM of 0 indicates no structural similarity and SSIM of 1 indicates identical images. For quantitative evaluation, the uncertainties given by the half-width at half-maximum are shown in FIGS. 10(b)-(c).

The fact that b′ is comparable to b, about an order of magnitude bigger than expected, has important implications for applications. It raises the possibility of all-acoustic spin control of NV centers within their full spin manifold without the need for a magnetic antenna. For sensing applications, a diamond bulk acoustic device can be practical and outperform a microwave antenna in several aspects: 1) acoustics waves provide direct access to all three qubit transitions, and the DQ qubit enables better sensitivity in magnetic metrology applications; 2) the micron-scale phonon wavelength is ideal for local selective spin control of NV centers; and 3) bulk acoustic waves contain a uniform stress mode profile and thus allows uniform field control on a large plane of spin ensemble, for example, from delta doped diamond growth process.

### Recitation of Embodiments

Embodiment 1. A system comprising:

a diamond substrate comprising at least one nitrogen-vacancy (NV) center therein;

an acoustic transducer mechanically coupled to the diamond substrate; and

a controller coupled to the acoustic transducer and configured to cause the acoustic transducer to generate acoustic waves within the diamond substrate to thereby drive a single-quantum (SQ) transition from a first spin state of the NV center to a second spin state of the NV center.

Embodiment 2. The system of Embodiment 1, wherein the first spin state comprises an mₛ=0 state and the second spin state comprises an mₛ=−1 state or an mₛ=+1 state.

Embodiment 3. The system of Embodiment 1, wherein the first spin state comprises an mₛ=−1 state or an mₛ=+1 state and the second spin state comprises an mₛ=0 state.

Embodiment 4. The system of any one of Embodiments 1-3, wherein the acoustic transducer is selected from the group consisting of: a bulk acoustic resonator (BAR), a high-overtone BAR (HBAR), and a semi-confocal HBAR (SCHBAR).

Embodiment 5. The system of any one of Embodiments 1-4, wherein the acoustic transducer is adhered to the diamond substrate.

Embodiment 6. The system of any one of Embodiments 1-5, wherein the acoustic transducer comprises a first thin metallic film adhered to the diamond substrate, a piezoelectric film adhered to the first thin metallic film, and a second thin metallic film adhered to the piezoelectric film.

Embodiment 7. The system of any one of Embodiments 1-6, wherein the acoustic waves are configured to drive the SQ transition via an alternating current (AC) strain in the diamond substrate.

Embodiment 8. The system of any one of Embodiments 1-7, further comprising a light source or a detector in optical communication with the NV center.

Embodiment 9. The system of Embodiment 8, wherein the light source or the detector is in optical communication with the NV center via a microscope objective.

Embodiment 10. The system of Embodiment 8 or 9, wherein the controller is further coupled with the light source or the detector and further configured to cause the light source to direct light to the NV center to thereby drive the NV center from a first electronic state to a second electronic state or to cause the detector to detect a fluorescence signal emitted by the NV center, the fluorescence signal indicative of a spin state of the NV center.

Embodiment 11. The system of any one of Embodiments 1-10, further comprising at least one magnet configured to introduce a Zeeman splitting between the first spin state and the second spin state.

Embodiment 12. The system of any one of Embodiments 1-11, wherein the controller is further configured to cause the acoustic transducer to generate acoustic waves within the diamond substrate to sensitize the NV center to a magnetic field, electric field, strain, or temperature in a vicinity of the NV center.

Embodiment 13. A method comprising:

generating acoustic waves within a diamond substrate comprising at least one NV center therein to thereby drive a single-quantum transition from a first spin state of the NV center to a second spin state of the NV center.

Embodiment 14. The method of Embodiment 13, wherein the first spin state comprises an mₛ=0 state and the second spin state comprises an mₛ=−1 state or an mₛ=+1 state.

Embodiment 15. The method of Embodiment 13, wherein the first spin state comprises an mₛ=−1 state or an mₛ=+1 state and the second spin state comprises an mₛ=0 state.

Embodiment 16. The method of any one of Embodiments 13-15, wherein the acoustic waves are configured to drive the SQ transition via an alternating current (AC) strain in the diamond substrate.

Embodiment 17. The method of any one of Embodiments 13-16, further comprising directing light to the NV center to thereby drive the NV center from a first electronic state to a second electronic state.

Embodiment 18. The method of any one of Embodiments 13-17, further comprising detecting a fluorescence signal emitted by the NV center, the fluorescence signal indicative of a spin state of the NV center.

Embodiment 19. The method of any one of Embodiments 13-18, further comprising introducing a Zeeman splitting between the first spin state and the second spin state.

Embodiment 20. The method of any one of Embodiments 13-19, further comprising generating acoustic waves within the diamond substrate to sensitize the NV center to a magnetic field, electric field, strain, or temperature in a vicinity of the NV center.

In describing the various embodiments, the specification may have presented a method and/or process as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process should not be limited to the performance of their steps in the order written, and one skilled in the art can readily appreciate that the sequences may be varied and still remain within the spirit and scope of the various embodiments. Similarly, any of the various system embodiments may have been presented as a group of particular components. However, these systems should not be limited to the particular set of components, now their specific configuration, communication and physical orientation with respect to each other. One skilled in the art should readily appreciate that these components can have various configurations and physical orientations (e.g., wholly separate components, units and subunits of groups of components, different communication regimes between components).

Although specific embodiments and applications of the disclosure have been described in this specification, these embodiments and applications are exemplary only, and many variations are possible.

What is claimed is:

1. A system comprising:
a diamond substrate comprising at least one nitrogen-vacancy (NV) center therein;
an acoustic transducer mechanically coupled to the diamond substrate; and
a controller coupled to the acoustic transducer and configured to cause the acoustic transducer to generate acoustic waves within the diamond substrate to thereby drive a single-quantum (SQ) transition from a first spin state of the NV center to a second spin state of the NV center.

2. The system of claim 1, wherein the first spin state comprises an mₛ=0 state and the second spin state comprises an mₛ=−1 state or an mₛ=+1 state.

3. The system of claim 1, wherein the first spin state comprises an mₛ=−1 state or an mₛ=+1 state and the second spin state comprises an mₛ=0 state.

4. The system claim 1, wherein the acoustic transducer is selected from the group consisting of a bulk acoustic resonator (BAR), a high-overtone BAR (HBAR), and a semi-confocal HBAR (SCHBAR).

5. The system of claim 1, wherein the acoustic transducer is adhered to the diamond substrate.

6. The system of claim 1, wherein the acoustic transducer comprises a first thin metallic film adhered to the diamond substrate, a piezoelectric film adhered to the first thin metallic film, and a second thin metallic film adhered to the piezoelectric film.

7. The system of claim 1, wherein the acoustic waves are configured to drive the SQ transition via an alternating current (AC) strain in the diamond substrate.

8. The system of claim 1, further comprising a light source or a detector in optical communication with the NV center.

9. The system of claim 8, wherein the light source or the detector is in optical communication with the NV center.

10. The system of claim 8, wherein the controller is further coupled with the light source or the detector and further configured to cause the light source to direct light to the NV center to thereby drive the NV center from a first electronic state to a second electronic state or to cause the detector to detect a fluorescence signal emitted by the NV center, the fluorescence signal indicative of a spin state of the NV center.

11. The system of claim 1, further comprising at least one magnet configured to introduce a Zeeman splitting between the first spin state and the second spin state.

12. The system of claim 1, wherein the controller is further configured to cause the acoustic transducer to generate acoustic waves within the diamond substrate to sensitize the NV center to a magnetic field, electric field, strain, or temperature in a vicinity of the NV center.

13. A method comprising:
generating acoustic waves within a diamond substrate comprising at least one NV center therein to thereby drive a single-quantum transition from a first spin state of the NV center to a second spin state of the NV center.

14. The method of claim 13, wherein the first spin state comprises an mₛ=0 state and the second spin state comprises an mₛ=−1 state or an mₛ=+1 state.

15. The method of claim 13, wherein the first spin state comprises an mₛ=−1 state or an mₛ=+1 state and the second spin state comprises an mₛ=0 state.

16. The method of claim 13, wherein the acoustic waves are configured to drive the SQ transition via an alternating current (AC) strain in the diamond substrate.

17. The method of claim 13, further comprising directing light to the NV center to thereby drive the NV center from a first electronic state to a second electronic state.

18. The method of any claim 13, further comprising detecting a fluorescence signal emitted by the NV center, the fluorescence signal indicative of a spin state of the NV center.

19. The method of claim 13, further comprising introducing a Zeeman splitting between the first spin state and the second spin state.

20. The method of claim 13, further comprising generating acoustic waves within the diamond substrate to sensitize the NV center to a magnetic field, electric field, strain, or temperature in a vicinity of the NV center.
